(19) United States
(12) Patent Application Publication
(10) Pub. No.: US 2007/0111489 A1
(43) Pub. Date: May 17, 2007

(54) METHODS OF PRODUCING A SEMICONDUCTOR BODY AND OF PRODUCING A SEMICONDUCTOR DEVICE

(76) Inventors: Geoffrey Jude CRABTREE, Vancouver, WA (US); Harry Milan Prothero, Yacolt, WA (US)

Correspondence Address: MCGLEW & TUTTLE, PC, P.O. BOX 9227, SCARBOROUGH STATION, SCARBOROUGH, NY, 10510-9227, US

(21) Appl. No.: 11/560,568

(22) Filed: Nov. 16, 2006

Related U.S. Application Data
(60) Provisional application No. 60/737,612, filed on Nov. 17, 2005.

(51) Int. Cl. H01L 21/00

(52) U.S. Cl. 438/500

(57) ABSTRACT

A source melt is formed by melting a source material comprising a semiconductor material. A portion of the source melt is directionally recrystallized to form an intermediate crystal and a residue portion that includes impurities. The residue portion is disposed of. Subsequently, at least a portion of the intermediate crystal is melted in a container to form a pool comprising at least the portion of the melted intermediate crystal. A semiconductor body is produced, by crystallising at least part of the pool. The semiconductor body may subsequently be transformed, for instance from an ingot form to a wafer form. A semiconductor device, such as one comprising a photovoltaic cell, may be produced from such a wafer.

In a first aspect, the present invention relates to a method of producing a semiconductor body. In a second aspect, the present invention relates to a method of producing a semiconductor device, such as a solar cell.

For the production of semiconductor devices, typically semiconductor wafers, cut from a larger semiconductor body with a certain quality are required. One of the parameters affecting the quality is the level of presence of undesired impurities that may adversely affect semiconductor device performance. Metal impurities are typically of specific concern.

The quality grade of the semiconductor body, and the wafers cut therefrom, depends on the quality grade of the source material from which the semiconductor body is formed. Consequently, a manufacturer of such semiconductor bodies has only limited choice of source material to employ.

In accordance with a first aspect of the invention, there is provided a method of producing a semiconductor body comprising a semiconductor material, the method comprising:
providing a source material comprising the semiconductor material;
melting the source material forming a source melt;
directionally recrystallizing a portion of the source melt to form an intermediate crystal and a residue portion;
disposing of the residue portion.

Directionally recrystallizing allows control of the location of impurities in the semiconductor sytem. It may involve a solid/liquid interface that moves relative to the solidified crystal. The presence of the liquid source melt in contact with the solidifying crystal is believed to have a purifying effect on the semiconductor material that is being solidified in the crystal, by virtue of redistribution of impurities between the liquid in the melt and the solid in the crystal being formed. Such segregation of impurities into the liquid results in impurities preferentially remaining in the melt to form the residue portion.

The residue portion may be kept separate from the intermediate crystal by breaking the contact between the intermediate crystal and the source melt before the source melt is fully depleted. This may be achieved by pulling the intermediate crystal from a portion of the source melt and leaving behind the residue portion in the melt.

Alternatively, the residue portion or part thereof may be allowed to solidify onto the intermediate crystal and be subsequently removed from the intermediate crystal, for instance mechanically.

The method of producing the semiconductor body may then be continued by:
melting at least a portion of the intermediate crystal in a container to form a pool comprising at least the portion of the melted intermediate crystal;
crystallizing at least part of the pool to form the semiconductor body.

By first producing the intermediate crystal as described and then melting the intermediate crystal, the manufacturer of the semiconductor body has a wider range of grades of semiconductor source material available to produce the semiconductor body from. For instance, scrap material may now be used as a source material, including so-called pot scrap, which is a by-product growing of semiconductor bodies using a so-called Czochralski method.

During the recrystallizing of the intermediate crystal the temperature of the source melt is preferably controlled. Herewith the segregation of impurities may be controlled.

Optionally, also a temperature gradient in the source melt and/or in the intermediate crystal is controlled.

Preferably, the intermediate crystal is a single crystal. It has been found that a lower content of the impurities is trapped in the intermediate crystal than is the case in a polycrystalline intermediate crystal.

Material from another source may be melted before, during, or after melting of the at least a portion of the intermediate crystal and added to the pool. This may be achieved, for instance, by co-melting, blending or mixing.

The appearance of the semiconductor body may be transformed, for instance from an ingot form to a wafer form. Such transforming may comprise cutting the semiconductor body into wafers. Optionally, the wafers may be polished and/or etched.

In accordance with another aspect of the invention, these wafers may be used in a method of producing a semiconductor device, further comprising the steps of
producing a doping junction in the wafer; and
applying further process steps to form the semiconductor device.

The invention will be described hereinafter in more detail by way of example and with reference to the accompanying drawings, wherein

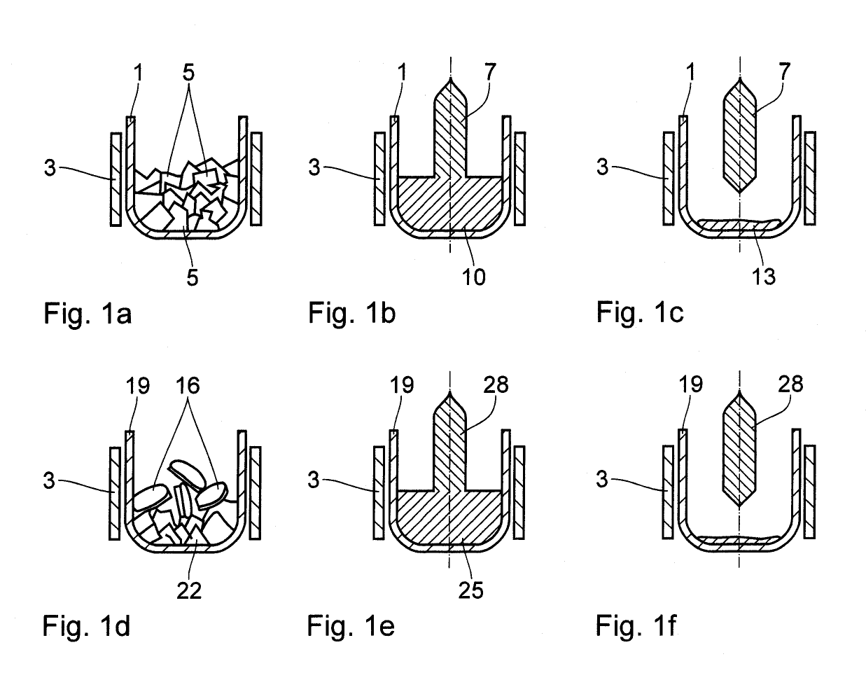

FIG. 1 (parts a to f) schematically shows a process sequence of producing a semiconductor body according to an embodiment of the invention.

In the Figures like reference numerals relate to like components.

Referring to FIG. 1 there is shown, in parts a to f, a process sequence of producing a semiconductor body in the form of an ingot 28, which allows the use of a low grade source material through recrystallization in processes for which higher purity source material is desired or required.

FIG. 1a shows, in cross section, a first crucible 1 surrounded by a heater 3. The heater may be one of any suitable kind, such as, for example, a current-fed resistive heater, and may be part of a furnace. The first crucible has been loaded with a source material in the form of pieces 5 of rocks and chunks comprising a low-grade semiconductor material. This may be any type of semiconductor material, of which silicon is a widely used example. Metallurgical grade silicon may also be used. In the following explanation, the semiconductor will be assumed to be silicon.

In the present example, the crucible is formed of a barium-coated quartz material.

The low-grade silicon may be provided in the form of, for instance, scrap material including waste products of other processes. It may comprise so-called pot scrap, which is silicon that was left behind in a crucible after performing Czochralski growth. It may also comprise other forms such as small pieces, dust, wasted or rejected wafers or fragments thereof from the solar cell or other semiconductor industries.

The crucible loaded with the low-grade silicon is heated sufficiently to allow melting of the silicon to form a source melt. Typically, the melting point of silicon is about 1421° C. Then an intermediate crystal 7 is pulled from the source melt 10, as is schematically shown in FIG. 1b. This may be accomplished using any suitable crystal pulling method, including the so-called Czochralski method.

A Czochralski crystal growing method typically comprises the following steps:
1) A crucible, usually made of a material comprising fused silica or quartz, is loaded with a charge of silicon and optionally supplemented with dopant impurity atoms such as boron or phosphorus or any other atom from the groups III or V from the periodic system;
2) the crucible is placed inside a growth chamber;
3) the growth chamber is then evacuated by substantially withdrawing gas present inside;
4) The growth chamber is then back-filled with an inert purge gas, normally in the form of Argon, to inhibit the entrance of atmospheric gases into the melt during crystal growing;
5) The silicon charge inside the growth chamber is then melted.
6) A seed of crystalline silicon (typically having a diameter or lateral size of between 3 and 10 mm, for example about 5 mm, and a length of between 100-300 mm) is introduced into the molten silicon. The seed may have predetermined orientation tolerances;
7) The seed crystal is then pulled upwards at a controlled rate. The seed crystal may be rotated, or the crucible, or both are rotated in opposite directions while this pulling process occurs.

Further details on Czochralski growth may be found in F. Shimura, Semiconductor Silicon Crystal Technology, Academic Press (San Diego, Calif., 1989), which is incorporated herein by reference.

Other methods of crystallization, however, can be used for purification, preferably if such a method is able to directionally crystallize the melt. Directional crystallization allows control of the location of impurities within the resulting silicon block. This region of high concentration of impurities would be the residue portion that can then be removed by mechanical means. An example of such a method of crystallization is the so-called float-zone process.

In the remainder of this explanation, the directional crystallization method will be assumed to be according to the Czochralski method. In essence, the solidification of the melted silicon that results in the intermediate crystal, is initiated by the insertion of a piece of solid silicon into the liquid silicon forming the source melt. Controlling the heat input and thermal conditions of the furnace in addition to the pulling rate, allows the silicon to crystallize onto the silicon piece, which was inserted into the melt. Typically, the crucible 1, the intermediate crystal 7, or both, may be rotated about a central vertical axis during the pulling, at a controlled rate.

Crystallization of the intermediate crystal may be continued until nearly the entire charge of silicon has crystallized into the intermediate crystal 7, which situation is shown in FIG. 1c. During the intermediate crystallization process, impurities will segregate between the solid and liquid to a different extent. The segregated impurities will be contained in the residue portion 13 of the source melt that is left behind in the crucible 1.

The residue portion is disposed of, so as to avoid re-introducing the segregated impurities into the remainder of the process.

It is believed that metallic impurities, which may be of concern for the electrical properties of the semiconductor body to be produced, tend to segregate significantly. The pulling of the intermediate crystal is therefore believed to result in a significant reduction in these and presumably also other harmful impurities.

The segregation effect is believed to take place in any form of solidification. The purification effect has been found to be the most pronounced by employing controlled solidification resulting in an essentially single crystalline intermediate crystal. However, in cases where the intermediate crystal had lost its single crystalline structure and therefore had a polycrystalline structure, the purification effect has still been found sufficient to yield a material that was useable as a source material for growing a crystal for use as base material for fabricating a solar cell.

Also, keeping the level of crystal defects in the single crystalline intermediate crystal as low as possible enhances the purification effect, as it is believed that defects may form getter sites for impurities.

In a next step, which is illustrated in FIG. 1d, pieces of the intermediate crystal 7 have been charged into a container, which in the embodiment as shown is in the form of a second crucible 19. Preferably, the second crucible 19 is different from the first crucible 1 that was used for containing the source melt so as to avoid re-inserting parts of the residue portion 13 into the remainder of the process.

These pieces have been schematically represented as discs 16 cut from the intermediate crystal 7, but they may be provided in a different form. For example, the intermediate crystal may be mechanically broken into (small) pieces. The size of the pieces may be controlled to facilitate the process of loading into a container, for instance a crucible, for the final growth. The intermediate crystal pieces can be blended with other forms of silicon. One of the benefits would be to optimise the process of loading the charge into a crucible.

Pieces or discs may be etched and dried to remove surface contamination before loading them into the second crucible 19.

Preferably, the resistivity of the intermediate crystal and/or that of the individual discs or pieces may be determined. This information will facilitate an accurate determination of amount of doping atoms that need to be added to the final charge in order to obtain a desired value of the resistivity.

In addition to the pieces 16 of the intermediate crystal 7, but this is optional, pieces 22 of silicon from another source have been loaded into the second crucible 19. These pieces 22 may be high-grade virgin silicon pieces of sufficient quality to grow the semiconductor body, or other pieces from another intermediate crystal.

The second crucible 19 together with these pieces 16 of the intermediate crystal is then heated to melt the pieces 16 of the intermediate crystal and thereby forming a pool 25 (see FIG. 1e) that comprises material originating from the intermediate crystal 7. At least part of the pool 25 is then crystallized to form the semiconductor body in the form of an ingot 28. It should be noted that the crystallization may be performed using the Czochralski method, as schematically depicted in FIGS. 1e and 1f, or using another suitable method such as cooling off in a die to form a polycrystalline semiconductor body.

Amongst the benefits of employing the Czochralski method during the recrystallisation phase is that impurities have one more chance to segregate out of the crystal forming the semiconductor body. Also, the resulting ingot that forms the semiconductor body may have a diameter as large as 4 inches (approximately 10 cm) or more, such as for instance 5 inches (12.5 cm) or 6 inches (15 cm).

Optionally, the second crystallisation is performed using again a directional recrystallization method to form a second intermediate crystal. The steps corresponding to FIGS. 1b and 1c may thus be repeated one or more times using prior consecutively grown intermediate crystals, before advancing to the final crystallisation steps corresponding to FIGS. 1c to 1e.

In another embodiment, instead of loading pieces of the final intermediate crystal into a crucible, the final intermediate crystal may be melted by gently lowering it into a pool containing pre-melted silicon in the second crucible 19. The pre-melted silicon may be obtained, for instance, by melting a relatively small amount of silicon 22 from another source in the second crucible 19. Amongst benefits of such an embodiment would be that the intermediate crystal can remain suspended in the growing apparatus while the first crucible 1 with the residue portion 13 is replaced with the second crucible 19.

The grown ingot may be further processed. For instance, it may be cut into wafers, for instance by sawing to obtain a semiconductor body in the form of a wafer.

The wafers may optionally be etched and/or polished before them to be further processed to form a semiconductor device, for instance comprising a photovoltaic cell. An example of such a photovoltaic cell may be a solar cell.

Typically, in order to produce such a semiconductor device a doping junction may be produced in the wafer to form a p-n junction. Other process steps may also be applied, to form the semiconductor device, including one or more steps selected of the group of lithographic steps, (local) oxide growth, application of electrical contacts, etching, polishing steps.

The bulk minority carrier lifetime is a good indicator of crystal quality, as it has been correlated to final electrical performance of solar cells. An analysis of average lifetime values of silicon crystals grown with some amount of purified pot scrap silicon, has been performed. The pot scrap silicon first been purified by forming an intermediate crystal using the Czochralski growth method as set out above. A comparison was made with silicon crystals grown with a standard poly silicon mix of high grade poly silicon which included chips and chuncks as obtained by the so-called Siemens process and optionally also granular silicon beads as obtained by a fluidised bed process.

The results indicate that crystals grown from intermediate crystallized pot scrap, one form of low grade silicon originating from a Czochralski growth process, have lifetimes no different than using higher grade silicon.

With the methodology described above, low grade source material that before was typically not desirable for production of silicon crystals for the solar industry, can now be purified using the present invention. Silicon pot scrap, for instance, is much cheaper than (high-grade) virgin silicon. Thus, a method to purify this silicon provides an overall cheaper silicon supply. The use of low grade silicon provides lower cost silicon and augments the silicon supply by making unusable silicon usable. Using purified low grade silicon, in for instance a solar cell fabrication process or in another semiconductor device fabrication process, provides improved electrical results over the use of unpurified silicon.

While the illustrative embodiments have hereinbefore been described with particularity, it will be understood that various other modifications will be readily apparent to, and can be easily made by one skilled in the art without departing from the spirit of the invention. Accordingly, it is not intended that the scope of the following claims can be limited to the examples and descriptions set forth herein but rather that the claims be construed as encompassing features which would be treated as equivalents thereof by those skilled in the art to which this invention pertains.

1. A method of producing a semiconductor body comprising a semiconductor material, the method comprising
providing a source material comprising the semiconductor material;
melting the source material forming a source melt;
directionally recrystallizing a portion of the source melt to form an intermediate crystal and a residue portion;
disposing of the residue portion;
melting at least a portion of the intermediate crystal in a container to form a pool comprising at least the portion of the melted intermediate crystal;
crystallizing at least part of the pool to form a semiconductor body.

2. The method of claim 1, wherein directionally recrystallizing comprises:
pulling the intermediate crystal from a portion of the source melt.

3. The method of claim 2, wherein the pulling of the intermediate crystal is done in accordance with the Czochralski method.

4. The method of claim 1, further comprising controlling the temperature of the source melt during directionally recrystallizing.

5. The method of claim 1, wherein the intermediate crystal is essentially a single crystal.

6. The method of claim 1, comprising performing the melting of the source material in a crucible.

7. The method of claim 6, wherein said crucible is a first crucible and wherein said container comprises a second crucible.

8. The method of claim 6, comprising performing the crystallizing by pulling the semiconductor body in accordance with the Czochralski method.

9. The method of claim 1, wherein the source material comprises scrap material.

10. The method of claim 1, wherein the source material comprises mainly silicon.

11. The method of claim 1, comprising melting material from another source before during or after melting of at least a portion of the intermediate crystal, and adding it to the pool.

12. The method of claim 1, further comprising transforming the semiconductor body from an ingot form to a wafer form, whereby the transforming comprises cutting the semiconductor body into wafers, and optionally polishing the wafers and optionally etching the wafers.

13. A method of producing a semiconductor device, comprising the steps of
providing a wafer obtained in accordance with the method of claim 10; and
producing a doping junction in the wafer;
applying further process steps to form the semiconductor device.

14. The method of claim 13, wherein the semiconductor device comprises a photovoltaic cell.
